(19) United States
(12) Patent Application Publication
(10) Pub. No.: US 2008/0206896 A1
(43) Pub. Date: Aug. 28, 2008

(54) METHOD FOR REPAIRING LIQUID CRYSTAL DISPLAY PANEL

(75) Inventor: Yanjiang FAN, Beijing (CN)

Correspondence Address: SHERIDAN ROSS PC, 1560 BROADWAY, SUITE 1200, DENVER, CO, 80202, US

(73) Assignee: BEIJING BOE OPTOELECTRONICS TECHNOLOGY CO., LTD, Beijing (CN)

(21) Appl. No.: 11/954,700

(22) Filed: Dec. 12, 2007

(30) Foreign Application Priority Data
Dec. 13, 2006 (CN) 200610165137.8

(51) Int. Cl. H01L 21/70

(52) U.S. Cl. 438/4; 257/E21.535

(57) ABSTRACT

Provided is a method for repairing a LCD panel. An opaque substance is disposed within a region on the thin film transistor panel of LCD panel corresponding to at least one pixel with the bright spot defect before forming a cell, or within a region on the LCD panel corresponding to at least one pixel with the bright spot defect after forming a cell.

The present application claims the priority of the Chinese patent application No. 200610165137.8 filed with the Chinese Patent Office on Dec. 13, 2006, the entire content of which is incorporated herewith by reference.

### BACKGROUND OF THE INVENTION

The present invention relates to a method for repairing a liquid crystal display (LCD) panel, and more particularly, to a method for repairing a LCD panel with a bright spot defect.

A liquid crystal display (LCD) is a very popular display at present. The LCD works on the principle that with the physical property of liquid crystal, the arrangement of the liquid crystal becomes regularly so that light can be transmitted through easily when voltage is applied, while the arrangement becomes disorder so that light is blocked when voltage is not applied, and thus an image is formed and colors are displayed on a screen. Since the process for fabricating the LCD is very complicated, it is almost inevitable to cause spot defects due to process error during the manufacturing process. There are two primary kinds of spot defects. One kind is bright spot defect, and the other kind is dark spot defect. Since human eyes are more sensitive to a bright spot and are less sensitive to a dark spot, only the dark spot rather than the bright spot would be allowed to occur in a product in high quality. In this regard, the bright spot defect can be repaired as a dark spot defect to the best of ability during the manufacturing process.

The general method for repairing the bright spot defect is converting a bright spot into a dark spot by breaking down normal operation of a pixel transistor. It is effective to repair the bright spot due to metal residue and the like with such a repair method, while for repairing the bright spot induced by a foreign article and the like, this method may easily cause a defect of bright line worse than a bright spot defect.

### SUMMARY OF THE INVENTION

In view of the problems in the related art, the present invention is to provide a method for repairing a LCD by utilizing optical characteristic in displaying of a LCD so as to avoid the problems in the related art caused by utilizing electrical characteristic to repair bright spot defect.

In order to achieve the above object, one aspect of the present invention provides a method for repairing a LCD panel. The LCD panel comprises a thin film transistor panel. The method comprises the following steps. The thin film transistor panel comprising a plurality of pixels is provided, wherein at least one pixel has a bright spot defect. And an opaque substance is disposed on the thin film transistor panel within a region corresponding to the at least one pixel with the bright spot defect.

In an embodiment, the opaque substance may be disposed on either side of or on both sides of the thin film transistor panel.

In an embodiment, the opaque substance may be disposed by deposition. Alternatively, the opaque substance may be disposed by printing.

Another aspect of the present invention provides a method for repairing a LCD panel. The method comprises the following steps. The LCD panel formed as a cell is provided. The LCD panel includes a thin film transistor panel and a color filter panel. The LCD panel has a plurality of pixels and at least one pixel has a bright spot defect. And an opaque substance is disposed on the LCD panel within a region corresponding to the at least one pixel with the bright spot defect.

In an embodiment, the opaque substance may be disposed on either side or both sides of the LCD panel.

In an embodiment, the opaque substance may be disposed by deposition. Alternatively, the opaque substance may be disposed by printing.

Compared with the related art, a layer of the opaque substance is disposed on a side of the thin film transistor panel or the LCD formed as a cell corresponding to the pixel with a bright spot defect for repairing the LCD panel in the embodiments of the present invention, so that the bright spot defect is converted into a dark spot defect, implementing the optical repair. As such, more serious bright line problem caused by utilizing electrical repair in the related art can be avoided, and thus the yield of LCD can be improved.

### BRIEF DESCRIPTION OF THE DRAWINGS

The foregoing and other features, aspects and advantages of the present invention will become more apparent from the following detailed description of the exemplary embodiments thereof in conjunction with the accompanying drawings, in which:

FIG. 1 is a plan view showing a bright spot defect in a conventional LCD.

FIG. 2 is a sectional view showing a bright spot defect in the LCD before forming a cell taken along line a-a′ in FIG. 1.

FIG. 3 is a sectional view showing a bright spot defect in the LCD after forming a cell taken along line a-a′ in FIG. 1.

FIG. 4 is a plan view showing a method for repairing a bright spot defect in a LCD according to the first embodiment of the present invention.

FIG. 5 is a sectional view taken along line b-b′ in FIG. 4.

FIG. 6 is a sectional view showing a method for repairing a bright spot defect in a LCD according to the second embodiment of the present invention.

### DESCRIPTION OF THE PREFERRED EMBODIMENTS

The specific exemplary embodiments of the present invention will be just shown and described by examples in the following detailed description. It will be understood by those skilled in the art that the invention could be embodied in many different forms and should not be construed as limited to the embodiments set forth herein. Further, in the context of the application, when an element is referred to as being “on” another element, it can be directly on the other element, or one or more intervening elements may be present therebetween so that the element is indirectly on the other element. The same reference numeral is used to denote the same element throughout the specification.

An embodiment of the present invention provides a method for repairing a LCD panel before forming a cell of the LCD with a thin film transistor panel and a color filter panel. The thin film transistor panel has a plurality of pixels and at least one of the pixels has a bright spot defect caused in manufacturing. According to the result detected by a detection apparatus before forming the cell, a layer of opaque substance, such as tungsten metal and the like, is deposited in a region corresponding to the pixel with the bright spot defect on a surface of glass substrate of the thin film panel by utilizing a deposition apparatus, so that light can be blocked effectively. As such, the bright spot defect becomes a dark spot defect, and thus product quality is improved to requirement for sale.

An embodiment of the present invention further provides a method for repairing a LCD panel after forming a cell of the LCD with a thin film transistor panel and a color filter panel. The LCD panel has a plurality of pixels, and at least one of the pixels has a bright spot defect caused in manufacturing. According to the result detected by a detection apparatus, a layer of opaque substance, such as tungsten metal and the like, is deposited in region corresponding to the pixel with the bright spot defect on a surface of the glass substrate of the LCD panel by utilizing a deposition apparatus, so that light can be blocked effectively. As such, the bright spot defect becomes a dark spot defect, and thus improving product quality is achieved.

In the above methods, the reason for forming the bright spot defect is unlimited, and any bright spot defect can be repaired using the method of the present invention. The apparatus and the deposition applied to the present invention are not limited to any specific kinds, as long as the thickness requirement of deposited film can be met and light can be blocked effectively. The thickness of the deposited film applied to the present invention is not specifically defined, as long as the subsequent attachment of a polarizer may not be affected and light can be blocked effectively. The deposition process may be performed either on the glass substrate on the side of the thin film transistor panel, or on the side of a color filter panel, or on the both sides at the same time, and each case may achieve the effect of repairing the LCD.

In order to make the foregoing objects, features, and advantages of the present invention more apparent, several embodiments are exemplified to give a detailed description with reference to the accompanying drawings.

Since a LCD panel has a cell-like configuration formed by assembling the thin film transistor panel and color filter panel, each of which has one substrate such as a glass substrate, the deposition may be performed on one selected glass substrate, and may also be performed on both glass substrates. Details will be given in the following with respect to the first embodiment and the second embodiment thereof, respectively.

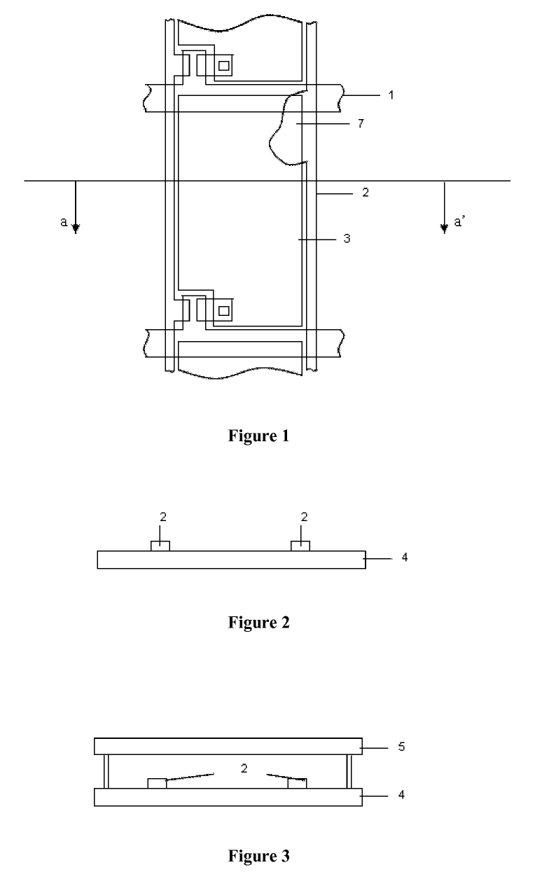

FIG. 1 is a plan view showing a bright spot defect in a pixel region of a LCD in general. FIG. 1 shows a pixel in the LCD. As shown in FIG. 1, the pixel comprises a scan line 1, a signal line 2, and a transparent electrode 3. A metal residue 7 occurs at a top right corner of the pixel area defined by the signal line 2 and the scan line 1, and thus leads to the bright spot defect.

FIG. 2 is a sectional view showing the pixel before forming cell of LCD taken along line a-a′ in FIG. 1. As shown in FIG. 2, the signal line 2 is distributed on a first glass substrate 4 of a thin film transistor panel.

FIG. 3 is a sectional view showing the pixel after forming a cell of the LCD taken along line a-a′ in FIG. 1. As shown in FIG. 3, the first glass substrate 4 is accurately aligned with a second glass substrate 5 of a color filter panel, and thus a cell-like configuration of LCD panel is formed.

As for the bright spot defect formed as shown in FIG. 1, it may be repaired by the following two specific methods according to the embodiments of the present invention.

### The First Embodiment

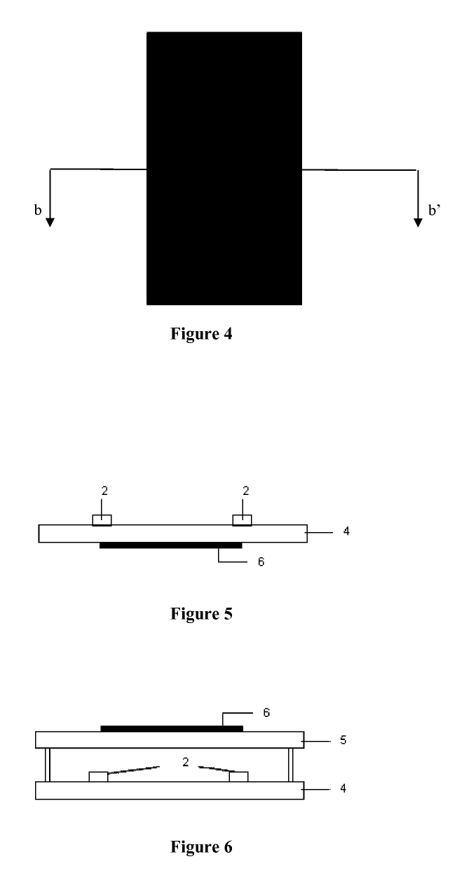

As shown in FIG. 5, a layer of opaque substance 6 is deposited or printed on the first glass substrate 4 in a region corresponding to the pixel with the bright spot defect according to the first embodiment of the present invention, so that light is blocked by the opaque substance 6. As such, the bright spot defect caused by the metal residue 7 can be converted into a dark spot defect, which is more acceptable than the bright spot defect, and the effect after repairing is shown in FIG. 4.

### The Second Embodiment

As shown in FIG. 6, an opaque substance 6 is deposited or printed on a surface of the second glass substrate 5 in a region corresponding to the pixel with the bright spot defect according to the second embodiment of the present invention. It can also function to block light and thus covert the bright spot defect into a dark spot defect.

Additionally, it should be noted that the deposition or printing process may be performed on either surface of the first glass substrate 4 of the thin film transistor panel and/or the second glass substrate 5 of the color filter panel, as long as it can be performed desirably and light can be blocked.

Finally, it should be appreciated that the embodiments described above are intended to illustrate but not to limit the present invention. Although the present invention has been described in detail with reference to the preferred embodiments, it should be understood by those skilled in the art that the present invention can be implemented with different material and apparatus as necessary, and that various modification and equivalents thereof can be made herein without departing from the spirit and scope of the present invention as defined in the appended claims.

What is claimed is:

1. A method for repairing a liquid crystal display (LCD) panel comprising a thin film transistor panel, the method comprising:
providing the thin film transistor panel comprising a plurality of pixels and at least one pixel with a bright spot defect; and
disposing an opaque substance within a region on the thin film transistor panel corresponding to the at least one pixel with the bright spot defect.

2. The method for repairing the LCD panel according to claim 1, wherein disposing the opaque substance is performed on either side of the thin film transistor panel.

3. The method for repairing the LCD panel according to claim 1, wherein disposing the opaque substance is performed on both sides of the thin film transistor panel.

4. The method for repairing the LCD panel according to claim 1, wherein the opaque substance is disposed by deposition.

5. The method for repairing the LCD panel according to claim 1, wherein the opaque substance is disposed by printing.

6. A method for repairing a LCD panel, the method comprising:
providing the LCD panel formed as a cell with a thin film transistor panel and a color filter panel, the LCD panel comprising a plurality of pixels and at least one pixel with a bright spot defect; and
disposing an opaque substance within a region on the LCD panel corresponding to the at least one pixel with the bright spot defect.

7. The method for repairing the LCD panel according to claim 6, wherein disposing the opaque substance is performed on either side of the LCD panel.

8. The method for repairing the LCD panel according to claim 6, wherein disposing the opaque substance is performed on both sides of the LCD panel.

9. The method for repairing the LCD panel according to claim 6, wherein the opaque substance is disposed by deposition.

10. The method for repairing the LCD panel according to claim 6, wherein the opaque substance is disposed by printing.
